(19) United States
(12) Patent Application Publication
(10) Pub. No.: US 2013/0222029 A1
(43) Pub. Date: Aug. 29, 2013

(54) METHOD FOR PULSE-LATCH BASED HOLD FIXING

(71) Applicant: QUALCOMM INCORPORATED, (US)

(72) Inventors: Benjamin J. Bowers, Raleigh, NC (US); Joshua L. Puckett, Raleigh, NC (US)

(73) Assignee: QUALCOMM INCORPORATED, San Diego, CA (US)

(21) Appl. No.: 13/756,283

(22) Filed: Jan. 31, 2013

Related U.S. Application Data
(60) Provisional application No. 61/592,809, filed on Jan. 31, 2012.

(51) Int. Cl. H03K 3/02

(52) U.S. Cl. CPC H03K 3/02
USPC 327/198

(57) ABSTRACT

A hold pulse latch is located in a data path between an output of a launch pulse latch and an input of a capture pulse latch. The hold pulse latch is configured to latch, and hold for the input of the capture patch, the output of the launch pulse latch in response to a hold pulse on its enable input. Optionally, at higher voltages, and frequency is high the launch pulse latch is changed to a transparent buffer mode. Optionally, the hold pulse latch is placed midway through the logic path between the launch pulse latch and the capture pulse latch.

### CLAIM OF PRIORITY UNDER 35 U.S.C. §119

The present Application for Patent claims priority to Provisional Application No. 61/592,809 entitled “METHOD FOR PULSE-LATCH BASED HOLD FIXING” filed Jan. 31, 2012, and assigned to the assignee hereof and hereby expressly incorporated by reference herein.

### FIELD OF DISCLOSURE

The present disclosure relates generally to pulse latches, and more specifically to pulse latch based hold fixing.

### BACKGROUND

In conventional flip-flop based logic circuits, the clock frequency must generally be slowed sufficiently to accommodate the delay associated with the circuit's slowest combinational logic paths.

FIGS. 1 and 2 illustrate a prior art flip-flop hold path and a pulse latch to pulse latch hold path. Flip-flop synchronization with the clock edge is widely used because it is matched with static timing analysis (STA). On the other hand, latches may also be used for storing the state. A latch is simpler and sometimes uses much less power than a flip-flop. However, it can be difficult to apply static timing analysis with latch design because of the data transparent behavior.

A latch can capture data during the sensitive time determined by the width of a pulse clock waveform. If the pulse clock waveform triggers a latch, the latch is synchronized with the clock in a similar manner to an edge-triggered flip-flop because the rising and falling edges of the pulse clock are almost identical in terms of timing.

Pulse latches require pulse generators that generate pulse clock waveforms from a source clock. The pulse width is chosen such that it facilitates the transition.

The setup times of pulse latches are expressed with respect to the rising edge of the pulse clock, and the hold times are expressed with respect to the falling edge of the pulse clock. This means that the representation of timing models of pulse latches is similar to that of the edge-triggered flip-flop.

Pulse latches are used in high speed and low power designs because they require one latch stage per clock cycle and can result in less dynamic power per latch. However, pulse latches have hold time specifications that are inherently harder to meet than flip-flops (FIGS. 1 and 2 illustrate this dynamic). A pulse latch has a longer hold time requirement because the latch is open for the duration of the pulse. Furthermore, to ensure reliable writing when operating at low voltage the pulse latch often needs a wider pulse than needed at higher voltage. This need further exacerbates the problem of staying within pulse latch hold requirements.

To fix this hold problem, there is a need to insert delay either in the clock path or the data path. Insertion of delay in the clock path is problematic because it can cause unwanted skew and will increase dynamic power (inserted buffers will have high activity rate). Typically, therefore, the data is delayed by delay buffers, to solve race conditions. However, staying within hold requirements at a wide range of voltages with delay buffers is becoming more difficult as technologies scale. Also, as voltage is reduced, delay scales non-linearly and delay variation increases. This means that the number of delay buffers needed to meet pulse latch hold requirements increases non-linearly as voltage is reduced. This results in increased power, substantial area overhead, and often in decreased speed. Thus a method is needed to solve low voltage hold problems of pulse latches with minimal area expense, power increase, and delay overhead at higher voltages.

### SUMMARY

Exemplary embodiments of the invention are directed to systems and methods for meeting pulse latch based hold requirements.

Further scope of the applicability of the described systems and methods will become apparent from the following detailed description, claims, and drawings. The detailed description and specific examples, while indicating specific examples of the disclosure and claims, are given by way of illustration only, since various changes and modifications within the spirit and scope of the description will become apparent to those skilled in the art.

In one exemplary embodiment, a circuit provides a data path comprising a launch pulse latch, a hold pulse latch and a capture pulse latch, and triggers the launch pulse latch and capture pulse latch on rising edges of a system clock and triggers the hold pulse latch on falling edges of the system clock. The launch pulse latch and hold pulse latch and their respective triggering on rising and falling edges of the system clock provide a frequency dependence for a hold time race through condition. The circuit can further comprise at least one combinational logic circuitry placed within the data path. In an aspect, hold pulse latch is configured to operate in a dual mode capacity, in one mode acting as a buffer at high frequencies and in the other mode acting as a hold pulse latch at low frequencies. The capture pulse latch can be configured to capture data from the data path after passing through the hold pulse latch. The circuit may further comprise a first pulse enable input for the hold pulse latch, a second pulse enable input for the launch pulse latch, a third pulse enable input for the capture latch, and an OR logic gate configured to OR the first pulse enable input with the second and third pulse enable inputs to form a fan-in logic system. The hold pulse latch may be further configured to transfer data to the at least one combinational logic when the negative edge of the system clock is triggered, wherein the triggering the negative edge of the system clock gates the data transferred from the launch pulse latch to the at least one combinational logic circuit by half a cycle of the system clock. The capture pulse latch may include an input and, in an aspect, reception of data at the capture latch input is dependent on an output of the hold pulse latch. In a further aspect, the output of the hold pulse latch is dependent on when the negative edge of the system clock is triggered and, in a related aspect, the period of the system clock is manipulated to directly affect the triggering of the hold pulse latch output. In an aspect, the circuit is configured such that an increase in system clock period results in an increased delay of the hold pulse latch output and the hold pulse latch is strategically placed within the circuit at high input voltages, and wherein the hold pulse latch is pulsed at low voltages to save power consumption.

In yet another exemplary embodiment, a method comprises triggering a launching pulse latch with a rising edge of a system clock and triggering a hold pulse latch with a falling edge of the system clock wherein the launching pulse latch and the hold pulse latch form part of a data path. The method further comprises providing at least one combinational logic circuitry, wherein the at least one combinational logic circuitry is placed within the data path. The method further comprises configuring the hold pulse latch to operate in a dual mode capacity acting as a buffer at high frequencies and a hold pulse latch at low frequencies. The method further comprises providing a capture pulse latch configured to capture data from the data path after passing through the hold pulse latch. The method further comprises providing a first pulse enable input for the hold pulse latch, enabling a second pulse enable input for the launch pulse latch, providing a third pulse enable input for the capture latch and connecting an OR logic gate configured to OR the first pulse enable input with the second and third pulse enable inputs to form a fan-in logic.

### BRIEF DESCRIPTION OF THE DRAWINGS

The accompanying drawings are presented to aid in the description of embodiments of the invention and are provided solely for illustration of the embodiments and not limitation thereof.

FIG. 1 illustrates a flip-flop to flip-flop hold path.

FIG. 2 illustrates a pulse latch to pulse latch hold path.

FIG. 3 illustrates a low-voltage operation of negative-edge triggered pulse latch demonstrating that at high voltage the B-phase latch's clock is held high and functions as a simple buffer.

FIG. 4 illustrates a negative-edge triggered pulse latch directly after a launch pulse latch, which can simplify implementation at a cost of a maximum frequency (FMAX).

FIG. 5 illustrates a flow diagram for an exemplary method of pulse latch hold fixing.

FIG. 6 shows a functional block diagram of example personal computing devices according to one or more exemplary embodiments.

### DETAILED DESCRIPTION

Aspects of the invention are disclosed in the following description and related drawings directed to specific embodiments of the invention. Alternate embodiments may be devised without departing from the scope of the invention. Additionally, well-known elements of the invention will not be described in detail or will be omitted so as not to obscure the relevant details of the invention.

The word “exemplary” is used herein to mean “serving as an example, instance, or illustration.” Any embodiment described herein as “exemplary” is not necessarily to be construed as preferred or advantageous over other embodiments. Likewise, the term “embodiments of the invention” does not require that all embodiments of the invention include the discussed feature, advantage or mode of operation.

The terminology used herein is for the purpose of describing particular embodiments only and is not intended to be limiting of embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Further, many embodiments are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored there in a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, the corresponding form of any such embodiments may be described herein as, for example, “logic configured to” perform the described action.

Hold time issues appear both at high and low voltages but are much more problematic at lower voltages. To fix hold time issues, prior art illustrates that one way is to insert delays either in the clock path or the data path. Clock insertion delay is problematic because it can cause unwanted skew and will increase dynamic power (inserted buffers will have high activity rates). As such, data is buffered to solve race conditions. However, closing hold at wide ranges of voltages with delay buffers is more difficult as technologies scale. One problem is that when voltage is reduced, delay scales non-linearly and delay variation increases. This means that the required number of hold buffers increases non-linearly as voltage is reduced. This results in increased power, substantial area overhead, and often in decreased speed.

It is therefore desirable to increase functionality associated with hold times of the latch circuitry by making hold races frequency dependent, especially at low voltage, to eliminate the need for extra hold buffers. Frequency dependence ensures reduction or even elimination of the hold race condition inherent in using pulse latches. A hold race condition is a condition wherein data arrives too early before a critical clock edge is triggered. It is one objective of the present disclosure to provide systems and methods to make the hold race condition frequency dependent and thus manageable by a system, to solve low voltage hold by eliminating hold problems at low voltage with minimal area expense, power increase or delay overhead experienced at higher voltages. The disclosed techniques have a the fundamental advantage over the prior art schemes in that they provide the above mentioned benefits, and also control the pulse width for the hold latch to be made more conservative for writeability, while allowing the configuration of a frequency dependent hold time race condition.

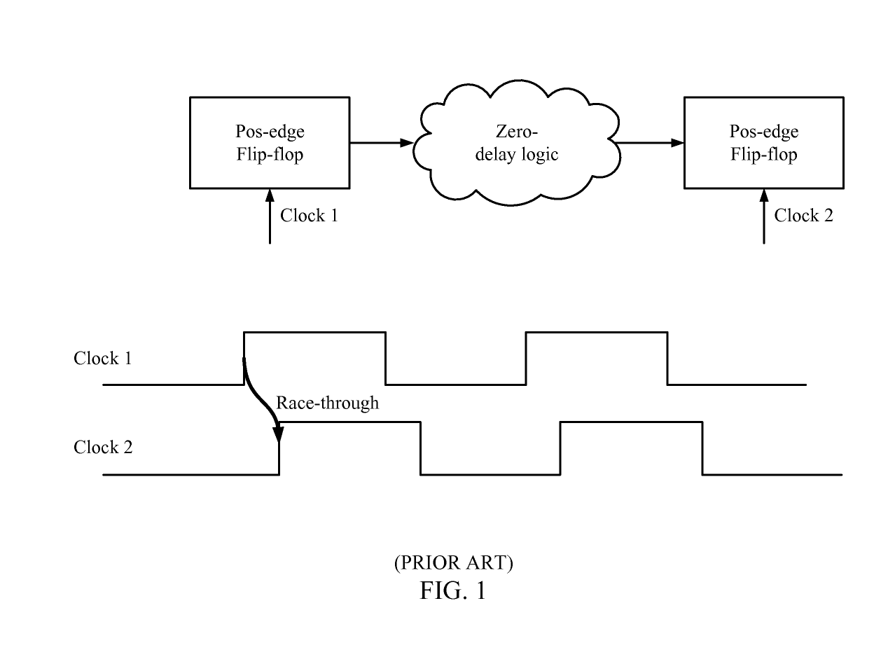

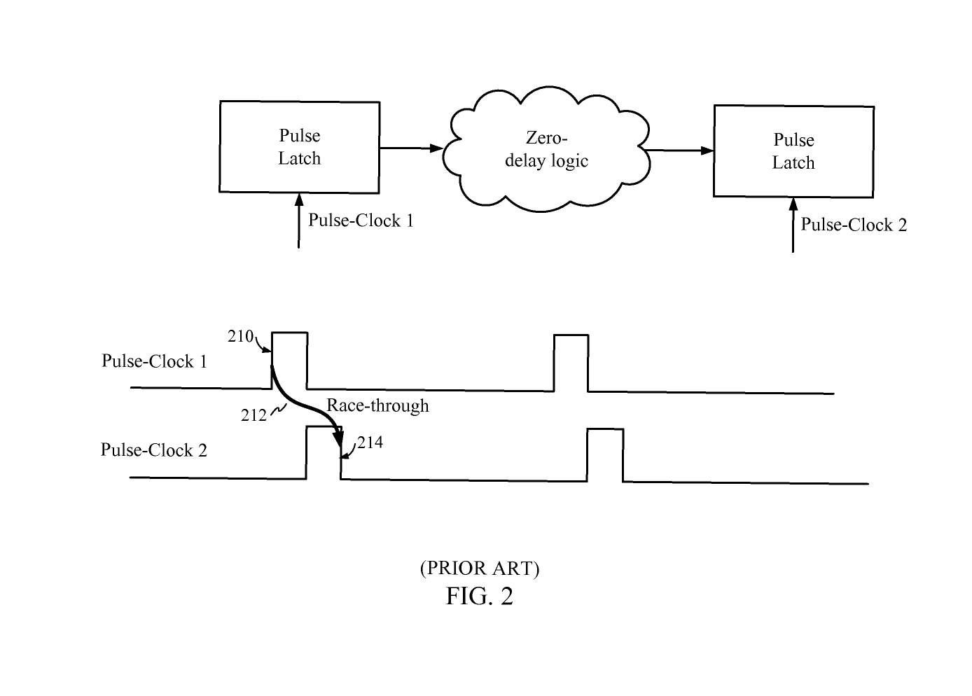

To solve issues of hold time and setup, prior art used single flip-flops and pulse latch designs as illustrated in FIGS. 1 and 2 wherein the data path contained zero delay logic. Setup time is the minimum amount of time the data signal, a synchronous signal, should be held steady before the clock event so that the data may be reliably sampled by the clock. Hold time is the minimum amount of time the data signal should be held steady after the clock event so that the data are reliably sampled. The single pulse latch approach used the following equations to solve hold and setup times:

D_{c2q1}+D_{dpath1}>D_{skew}+Dₚᵤₗₛₑ+D_{hold2 (To solve hold)}

D_{c2q1}+D_{dpath1}+D_{skew}<D_{period}+D_{setup2 (To solve setup)}

Wherein

| | |
|---|---|
| D_{c2q1} | Launch delay of first or launch pulse latch |
| D_{dpath1} | Path delay including the zero delay logic |
| D_{skew} | Delay difference between pulse clock 1 and pulse clock 2 |
| Dₚᵤₗₛₑ | Width of the pulse clocks 1 and 2 |
| D_{hold2} | Hold time of the second pulse latch (capturing latch) |
| D_{period} | Period of master clock (not shown in FIGS. 1 and 2) |
| Dₛₑₜᵤₚ₂ | Setup time of second pulse latch |

It can be seen from the equations, which capture the performance of the prior art, that in order to solve hold time issues, the sum of the launch delay of the first pulse latch and the path delay, including the zero delay logic had to be a specific value. That specific value had to be greater than the sum of the delay difference of the pulse clocks 1 and 2, the width of the pulse of the pulse clocks 1 and 2 combined and the hold time of the second pulse latch, i.e., the capturing latch.

Furthermore, to solve the setup problem, the prior art needed to have the sum of the launch delay of the pulse latch, the zero delay logic, and the delay difference between the pulse clocks 1 and 2 to be less than the sum of the period of the master clock (not shown) and the setup delay of the second pulse latch. Hold time is a race through condition, caused by data arriving too early. For example, FIG. 2 can illustrate a race through condition 212 as indicated from rising edge 210 to falling edge 214. In the prior art, this race through condition 212 is the difference between the rising edge of a first pulse clock (used to trigger a launching latch) and the falling edge of a second pulse clock (used to trigger a receiving latch). The race through condition 212 may also be referred to as hold time race condition, and can be managed by making it a frequency dependent function as illustrated below. By making the race condition frequency dependent, the race condition can be manipulated to be increased or decreased as well as eliminated, depending on the needs of the system in which the pulse latch circuits are implemented.

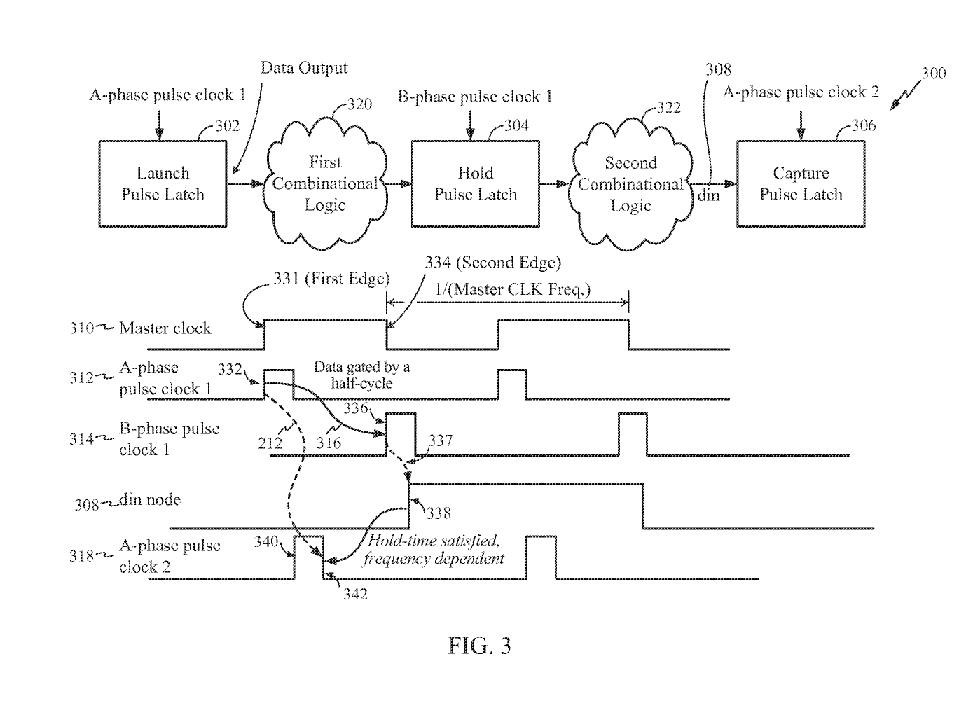

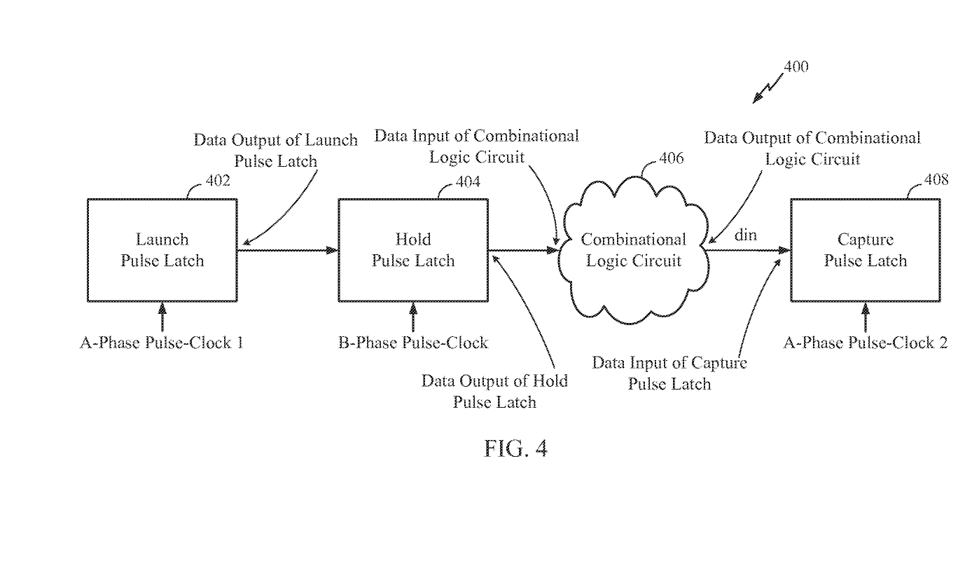

FIG. 3 illustrates one exemplary embodiment of a pulse latch based method and system to solve low voltage hold time problems at low voltages with minimal area expense, power increase, or delay overhead experienced at higher voltages. The below listed equations help illustrate different aspects of the embodiment. FIG. 3 is a block diagram of a digital system 300 employing clock domain boundaries between stages of combinational logic circuits. Digital system 300 includes a plurality of pulse latches, for example a first or launch pulse latch 302, a second or hold pulse latch 304, and a third or capture pulse latch 306 (collectively, “pulse latches 302, 304, 306”). The digital system 300 further includes a plurality of combinational logic circuits, for example, a first combinational logic circuit 320 and second combinational logic circuit 322. The data path between the pulse latches 302, 304, 306 can include any number of combinational logic circuits and may not necessarily be confined to two; for example the data path may include one combinational logic or greater than 2 combinational logics. The combinational logics may be split in half, to form “half logics” or may be separate logics. The hold pulse latch 304 may be designed to be changeable between being a pulse latch and being a transparent buffer, as discussed further below. The pulse latches 302, 304, 306 may have a functional operation of pipelining of the logic operation through the logic circuits and data paths. For example, the launch pulse latch 302 may be-operable to transfer data through the first combinational logic circuit 320. The hold pulse latch 304 may be operable to transfer data through the second combination logic circuit 322 upon satisfaction or completion of the hold time required. The capture pulse latch 306 may be configured to receive or capture the data output from the second combinational logic 322 via input signal Din. Referring to FIG. 3, launch pulse latch 302 is clocked utilizing A-phase pulse clock 1, 312 (hereinafter A-phase pulse clock 312) operating at a first frequency and phase. The hold pulse latch 304 is clocked utilizing B-phase pulse-clock 1, 314 (hereinafter B-phase pulse clock 314) operating at a second frequency and phase, and the capture pulse latch 306 is clocked utilizing A-phase pulse-clock 2, 318 (hereinafter A-phase pulse clock 318) operating at a third frequency and phase. Thus, the first combinational logic circuit 320 may operate at a different frequency and/or phase than the second combinational logic circuit 322. It is understood that the digital system 300 may include additional and/or fewer stages of combinational logic as will be discussed further in FIG. 4 below. Furthermore, it is understood that the digital system 300 may include different placement schemes for the placement of the hold pulse latch 304 as will further be discussed below.

Digital system 300 also includes a master clock 310 that establishes the clock domain for the system. The master clock 310, in an aspect, is configured to serve as a triggering mechanism for the pulse clocks that control the launch pulse latch 302, the capture pulse latch 306 and the pulse clock that controls the hold pulse latch 304. Referring to master clock 310, a rising edge 330 acts as a trigger for A-phase pulse-clock 312, causing a pulse rising edge 332. Pulse rising edge 332 triggers a transfer of data from the launch pulse latch 302 to the first combinational logic circuit 320. Placement of the hold pulse latch 304 is dependent on several parameters discussed further below. It may be noted that the placement of the hold pulse latch 304 may split a given larger combinational logic (not explicitly shown in FIG. 3) into several stages within a data path, e.g., two halves, which may be embodied by, for example, the first combinational logic 320 and the second combinational logic 322. Alternatively, the placement of the hold pulse latch 304 may keep an entire combinational logic (not explicitly shown in FIG. 3) intact on either side of the second or hold pulse latch 304. The launch pulse latch 302 may have a data and clock input (both shown, but not separately labeled). A hold time may be represented as a duration of time following the pulse rising edge 332, during which the output data must remain valid for the input of a receiving pulse latch to occur. Because of inherently hard to meet hold time specifications of pulse latches, the hold latch 304 may be advantageously utilized.

In one exemplary embodiment, the placement of the hold pulse latch 304 in the data path is critical in obtaining a frequency dependent hold time race through condition. For example, the hold pulse latch 304 may be placed at high voltage/high frequency conditions. This placement allows hold pulse latch 304 to operate in a dual mode capacity: 1) a buffer at high voltage/high frequency operations and 2) a hold pulse latch at lower voltages/lower frequencies. Other dual mode operations may also be configurable, such as high voltage/high frequency operations that yield a hold pulse latch at high voltages/frequencies and a transparent buffer at low voltages/frequencies. Low voltage/frequency operations will be used as exemplary embodiments, although high voltage/frequency operations can also be implemented. As such, the mode of the hold pulse latch 304 may be a buffer or a hold pulse latch, depending on the operating conditions. For example, a hold pulse latch mode of the hold pulse latch 304 may be an exemplary mode in low voltage/frequency operations, and a transparent buffer mode may be an exemplary mode in high voltage/frequency operations.

In one embodiment (not explicitly shown in FIG. 3), the hold pulse latch 304 may be configured to receive second combination logic circuit 322 output. In an aspect, as shown in FIG. 3, the hold pulse latch 304 is triggered by the rising edge 336 of the B-phase pulse clock 314, which is shown as caused by the a negative edge 334 of the master clock 310, thereby making the hold pulse latch 304 a negative triggered pulse hold latch, with respect to the master clock 310. In other words, in an aspect, the rising edge 336 of the B-phase pulse clock is configured to rise at the falling edge 334 of master clock 310. As also shown, the rising edge 330 of master clock 310 triggers A-phase pulse clock 312 causing the launch pulse latch 302 to transfer data to the input of the first combinational logic 320. At a particular time after the rising edge 330, which can be determined based on the frequency of the master clock 310, as further discussed below, the falling edge 334 of the master clock 310 causes the rising edge 336 of the B-phase pulse clock 314, which triggers the hold pulse latch 304.

The time between the rising edge 332 of the A-phase pulse clock 312 and the rising edge 336 of the B-phase pulse clock 314 is the time at which the data passes through the data path, to the output of the first combinational logic circuit 320 and to the input (shown but not separately numbered) of the hold pulse latch 304. That time is labeled “316” on FIG. 3 and may be referred to as a gated data time 316. The gated data time 316 is half a cycle of master clock 310 at which point the data has is passed on from the launch pulse latch 302 through the first combinational logic circuit 320 and to the hold pulse latch 304.

The rising edge 336 of the B-phase pulse clock 314 triggers the data transfer from the hold pulse latch 304 through the second combinational logic circuit 322 and thereafter to the capture pulse latch 306. In one exemplary embodiment, placing the hold pulse latch 304 in the middle of the data path (in essence splitting a larger combination logic into the FIG. 1 first and second combinational logic 320 and 322) allows for re-launching the data onto the second half of the data path. The data path input into the capture pulse latch 306 is represented by Din 308. Arrow 337 illustrates there is a small delay of time after the rising edge 336 before the data is received at Din 308. The data appears at Din 308 shortly after the hold pulse latch 304 starts to transfer the data through the data path and onto second combinational logic circuit 322. The data appearing at Din 308 is represented by rising edge 338, and the width of Din 308 being valid is represented by a full cycle of B-phase pulse clock 314. In other words, the width for which Din 308 remains valid is triggered initially by rising edge 336 and will be sustained until the next rising edge of B phase pulse clock 314.

One embodiment that may have the capability to manipulate (by increasing, decreasing or eliminating) hold time at low voltage with minimal area expense, power increase and delay overhead experienced at higher voltages is to selectively enable the latching function of the hold pulse latch 304 in the data path at higher voltages, where hold time is not as significant of an issue and wherein frequency is high. This allows the hold pulse latch 304 to operate as a buffer at high voltages/frequencies and then change a hold pulse latch at lower voltages/frequencies. As such, at lower voltages/frequencies, the hold pulse latch 304 may be pulsed with a negative edge triggered pulse, falling edge 334. Clock gating may be implemented by OR-ing (combining inputs at an OR gate) pulse latch 302 (the launch latch) enable with the hold pulse latch 304. The placement of the hold pulse latch 304 within the logic path is determined by attempting to limit low voltage frequency as little as possible. A logic path that is identified as a path in need of a hold pulse latch is called a hold critical path. Hold critical paths and low voltage frequencies may be identified through electrical path analysis such as transient simulation program with integrated circuit emphasis (SPICE) or some sort of static timing analysis. These analyses are reflected in the equations cited throughout the disclosure.

The use of the hold pulse latch 304 allows for mitigation of the race condition, by increasing the period of master clock 310. The mitigation of the race through condition is allowed because increasing the period of the master clock increases the time from the rising edge 336 (generated from having master clock 310 falling (falling edge 334) to the falling edge 342 of A-phase pulse clock, 318 (falling edge of the pulse latch 306)). This effect of the period of the master clock 310 on the race through condition makes the hold race condition frequency dependent. For example, the race through condition of the prior art 212 indicates that the data would race through the zero delay logic. In the absence of the hold pulse latch 304, such a race through would result in Din 308 changing at some point between the rising edge 340 and the falling edge 342. As demonstrated by digital system 300, the insertion of the hold pulse latch 304 creates a delay that results in Din 308 changing at a later time. The insertion of the hold pulse latch 304 can also make the race through condition frequency dependent, and thus allow a system or chip to manage the hold time race through condition using frequency manipulation.

In known conventional pulse latch based designs, the race conditions are frequency independent. This results in certain dangers and limitations because the race through condition cannot be fixed by lowering the frequency. In one exemplary embodiment of the disclosure, strategic placement of the hold pulse latch 304 within the data path allows for the race through condition to be frequency dependent, i.e., allows a controllable relationship between frequency and race through conditions. In one example, the hold pulse latch 304 is added to the data path, and is pulsed by the negative (or falling) edge 334 of the master clock 310. The relationship between the rising and falling edges of the master clock 310 is thus established as a factor in the race through condition as discussed above. This allows impacting the race through condition by varying, i.e., fluctuating, the master clock frequency. For example, by decreasing the master clock frequency, i.e., increasing the pulse width of the master clock 310, the system can increase a spacing between rising edge triggered pulses and falling edge triggered pulses. This makes the occurrence of input Din 308 (as a result of race through the circuit) dependent on when the falling edge 334 occurs, which makes the race through condition dependent on clock frequency.

In addition to increasing functionality by making hold race conditions frequency dependent, especially at low voltage, the present embodiment has several other advantages. One is that the second or hold pulse latch 304 is pulsed only at high voltages, (at the negative edge of master clock 310), which means additional power is saved at low voltages. Furthermore, the hold pulse latch 304 is needed only on hold critical paths; therefore an extra parasitic latch is not needed in all paths as master-slave flip flop designs necessitate.

Also, the pulse width for the hold pulse latch 304 can be made conservative for writeability.

The following equations help illustrate the modification of the dependence of the race through condition, to allow it to be frequency dependent. This illustrates one condition placed on an embodiment discussed above in relation to FIG. 3. The digital system 300 can adopt a maximum frequency that is inversely proportional to the minimum period at which the circuit can operate.

D_{period}/2>D_{skew}+Dₚᵤₗₛₑ₁+D_{hold2} (1)

Wherein

| | |
|---|---|
| D_{skew} | Delay difference between pulse clock 1 and pulse clock 2 |
| Dₚᵤₗₛₑ₁ | Width of the pulse clocks 312, 314 and 318 |
| D_{hold2} | Hold time of the capture pulse latch 306 |
| D_{period} | Period of the master clock 310 |

The maximum frequency, FMAX, which is inversely proportional to Dperiod/2 (the period of the master clock 310), is a maximum frequency at which the circuit can operate. FMAX can be useful in determining an optimum frequency, both high and low, for the operation of the hold pulse latch 304. FMAX can be calculated as the sum of the delay difference between A-phase pulse clock 312 and the A-phase pulse clock 318, the width of the A-phase pulse clocks 312 and 314 respectively, and the hold time of the capture pulse latch 306. FMAX may be considered an optimal high operating frequency of system 300 at which point the hold pulse latch 304 may be strategically inserted. As discussed above, this can allow for the hold pulse latch 304 to operate as a buffer at high frequencies, for example, without interrupting the data flow through the combinational logic, and thereafter can operate in a secondary latch mode, or hold mode, when the system 300 is operating at a reduced frequency/voltage.

Equation (2) shows there is another way to fix hold time issues and make the hold frequency dependent, which is alternative to equation (1). and either equation (1) or equation (2) can be satisfied to make hold frequency dependent:

D_{c2q1}+D_{dpath1}>D_{skew}+Dₚᵤₗₛₑ+D_{hold2} (2)

Wherein

| | |
|---|---|
| D_{c2q1} | Launch delay of the launch pulse latch |
| D_{dpath1} | Path delay |
| D_{skew} | Delay difference between pulse clock 1 and pulse clock 2 |
| Dₚᵤₗₛₑ | Width of the pulse clocks 1 and 2 |
| D_{hold2} | Hold time of the capture pulse latch |

It can be seen that the sum of the launch delay of the launch pulse latch 302 and the delay of the data path is greater than the delay consisting of the sum of the difference of A-phase pulse clocks 312 and 318 respectively, the width of the A-phase pulse clocks 312 and 318 and the hold time of the capture pulse latch 306. This is also illustrated in FIG. 3 wherein half a cycle of the master clock 310 (i.e., half the period) can be measured by summing the launch delay of the launch pulse latch 302 and the path delay of the first combinational logic circuit 320.

To achieve a hold time that is dependent on frequency, either one of the above equations (equation 1 or equation 2 respectively) will need to be satisfied. In essence, equations 1 and 2 illustrate that hold paths can be fixed by slowing down the frequency, which is accomplished by increasing the Dperiod.

Making hold frequency dependent helps overcome the inherent race through condition that exists in phase-based hold latches when their triggering clocks rise and the data can race through the hold pulse latch 304 and be captured by the capture pulse latch 306. To mitigate this by convention techniques additional buffering, for clock skewing, would be needed. The proposed method avoids the clock skewing by using a negative edge triggered (with respect to the system clock 310) hold pulse latch 304. In addition, simple phase-based hold latches would not make the hold races frequency dependent and would make them much more difficult to debug in hardware.

To solve the setup issue, the delay logic is defined by conditional constructs that help place the setup of the delay logic at specified locations within the data path. For example, one embodiment would define a conditional construct as the following: if the sum of the clock-to-Q launch delay of the launch pulse latch 302 and the delay through the first combinational logic circuit 320 (between the launch pulse latch 302 and the hold pulse latch 304) is less than half the period of the master clock 310, then the sum of half the period of the master clock 310 and the clock-to-Q launch delay of the second pulse latch 304 and the delay through the second combinational logic circuit 322 and the skew between A-phase pulse clocks 312 and 318 respectively, is less than the sum of the period of the master clock 310 and the capturing pulse latch 306. Otherwise, if the above condition is not met, then the sum of clock-to-Q launch delay of the launch pulse latch 302 and the delay through the first combinational logic circuit 320 and data-to-Q flow-through delay of the second or hold hold-only pulse latch 304 and the delay of second combinational logic circuit 322 along with the skew between A-phase pulse clock 312 and 318 respectively, should be less than the sum of the period of the master clock 310 and the setup delay.
if:

D_{c2q1A}D_{dpath1A}<D_{period}/2 (3)

then:

D_{period}/2+D_{c2q1B}+D_{dpath1B}+D_{skew}<D_{period}+Dₛₑₜᵤₚ₂ (4)

else:

D_{c2q1A}+D_{dpath1A}+D_{d2q1B}+D_{dpath1B}+D_{skew}<D_{period}+Dₛₑₜᵤₚ₂ (5)

Wherein:

| | |
|---|---|
| D_{c2q1A} | Clock to Q launch delay of first or launch pulse latch 302 |
| D_{c2q1B} | Clock to Q launch delay of third or capture pulse latch 306 |
| D_{d2q1B} | Clock to Q launch delay of second of hold pulse latch 304 |
| D_{dpath1A} | Path delay including the first combinational logic circuit |
| | between pulse latches 302 and 304 |
| D_{dpath1B} | Path delay including the second combinational logic between |
| | the hold pulse latch 304 and the capture pulse latch 306 |
| D_{skew} | Delay difference between pulse clocks 312 and 318 |
| Dₚᵤₗₛₑ | Width of the pulse clocks 312, 314 and 318 |
| D_{hold2} | Hold time of the third or capture pulse latch 306 |
| D_{period} | Period of the master clock 310 |
| Dₛₑₜᵤₚ₂ | Setup time of the third or capture pulse latch 306 |

In cases where the second or hold pulse latch 304 is positioned at the output of pulse latch 302, then the delay of the first half combinational logic circuit 320 delay (D_{dpath1A}) component becomes zero, and the full data path delay must be accounted for in (Da_{path1B}) This can be provided by moving all of the data path logic into D_{dpath1B} the delay (D_{dpath1A}) becomes zero delay, i.e. there is zero combinational logic between the launch pulse latch 302 and the hold pulse latch 304. This is further shown and explained in reference to FIG. 4 below.

The FIG. 4 system 400 depicts yet another exemplary embodiment which may be advantageously employed. In the system 400, a negative-edge triggered pulse latch 404 is directly fixed to the output of a first or launch pulse latch 402. This method may be advantageous if placement of the hold pulse latch 404 within a data path are not available. This allows for all the combinational logic 406 to immediately follow the second or hold latch 404. This implementation advantageously utilizes the earlier method described in reference to FIG. 3, but may be simpler in design because it does not require strategic insertion in the center of the logic or data path and allows for the sharing of the combinational logic 406 for launch pulse latch's 402 pulse generation. To further distinguish this embodiment, the prior art only required generation of a pulse at a single clock edge. However, in this embodiment, the circuitry for generation of pulses (not explicitly shown) may be advantageously placed near the launch pulse latch 402. This allows for generating opposite-edge pulses at locations nearby their corresponding latches. The addition of the hold pulse latch 404 to the launch pulse latch 402 makes it possible to efficiently combine the effect of two opposite edge pulse latches into one shared circuit. It will be understood that, in the FIG. 4 exemplary embodiment, the sharing is not of combinational logic 406, but rather the sharing is of the pulse generation. This is effectively done by having opposite-edge pulse latches share the pulse generation and control the delay of the data path. While simplifying the circuit and logic, the maximum time for data transfer between the latches is now determined by the width of the master clock 310. In one embodiment, frequency can be lost if data is prematurely gated before going into the pulse hold latch 404. For example, launch pulse latch 402 may be pulsed prior to receiving all the data to be gated. This may result in a loss of frequency because the premature gating may cause the required period to be longer than would otherwise be required if the hold pulse latch 404 had been placed elsewhere. As such, when the hold pulse latch 404 is enabled, i.e., pulsed, if the loss of a maximum frequency FMAX is acceptable, for example, at low voltages when a hold race condition is of most concern, then this approach is a viable alternative because the delay of combinational logic 406 must be less than the delay of the master clock 310.

To further elaborate on the above example, having the entire data path in the second half of the cycle gives rise to the following equation:

D_{period}/2+D_{c2q1B}+(D_{dpath1A}+D_{dpath1B})+D_{skew}<D_{period}+Dₛₑₜᵤₚ₂ (6)

By manipulation, equation (6) can be rewritten as:

D_{c2q1B}+(D_{dpath1A}+D_{dpath1B})+D_{skew}<D_{period}/2+Dₛₑₜᵤₚ₂ (7)

Wherein:

| | |
|---|---|
| D_{c2q1A} | Clock to Q launch delay of launch pulse latch 302 |
| D_{c2q1B} | Clock to Q launch delay of the capture pulse latch 306 |
| D_{d2q1B} | Clock to Q launch delay of the hold pulse latch 304 |
| D_{dpath1A} | Path delay between the launch pulse latch 302 and the |
| | hold pulse latch 304 |
| D_{dpath1B} | Path delay between the hold hold-only pulse latch |
| | 304 and the capture pulse latch 306 |
| D_{skew} | Delay difference between A-phase pulse clocks 312 and 318 |
| Dₚᵤₗₛₑ | Width of the pulse clocks 312, 314 and 318 |
| D_{hold2} | Hold time of the capture pulse latch 306 |
| D_{period} | Period of the master clock 310 |
| Dₛₑₜᵤₚ₂ | Setup time of the capture pulse latch 306 |

This illustrates that now the sum of the delays of the half data paths must be less than half of the period of master clock 310, which may constrain maximum frequency. As such, there is a tradeoff consideration when it comes to placement of hold pulse latches. For example, if placement identification methods are available, then placement of a hold pulse latch, such as the hold pulse latch 304 or 404 may be ideal. Alternatively, however, and when such methods are not available, simpler design implementations are available to enable placement of a hold-only pulse latch, such as the hold pulse latch 404 directly after a launch pulse latch to simplify the circuit.

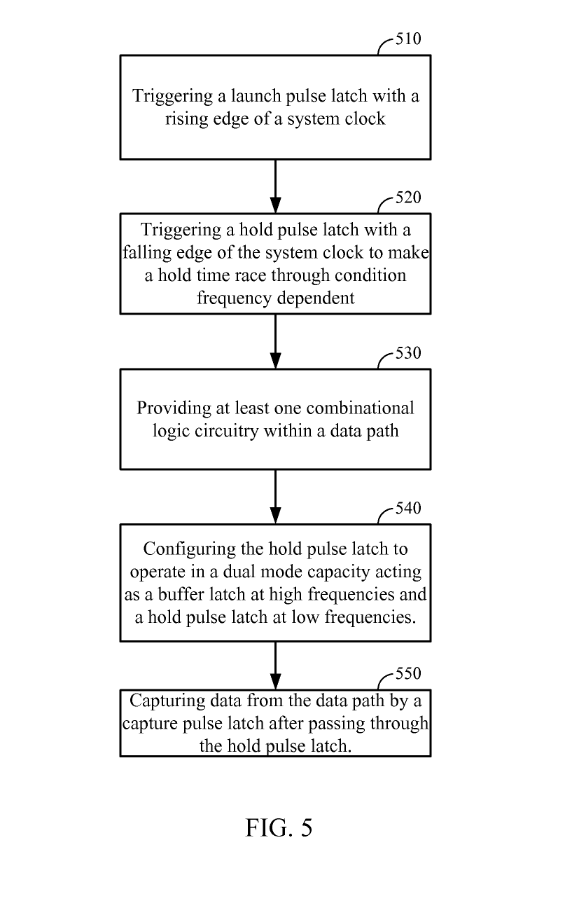

FIG. 5 illustrates a flow diagram for an exemplary method of pulse latch hold fixing.

The method comprises triggering, 510, a launch pulse latch with a rising edge of a system clock, triggering, 520, a hold pulse latch with a falling edge of the system clock to make a hold time race through condition frequency dependent, and providing, 530 at least one combinational logic circuitry within a data path. The method may also include configuring, 540, the hold pulse latch to operate in a dual mode capacity, acting as a buffer latch at high frequencies and a hold pulse latch at low frequencies. The method may further include capturing, 550, data from the data path by a capture pulse latch after passing through the hold pulse latch.

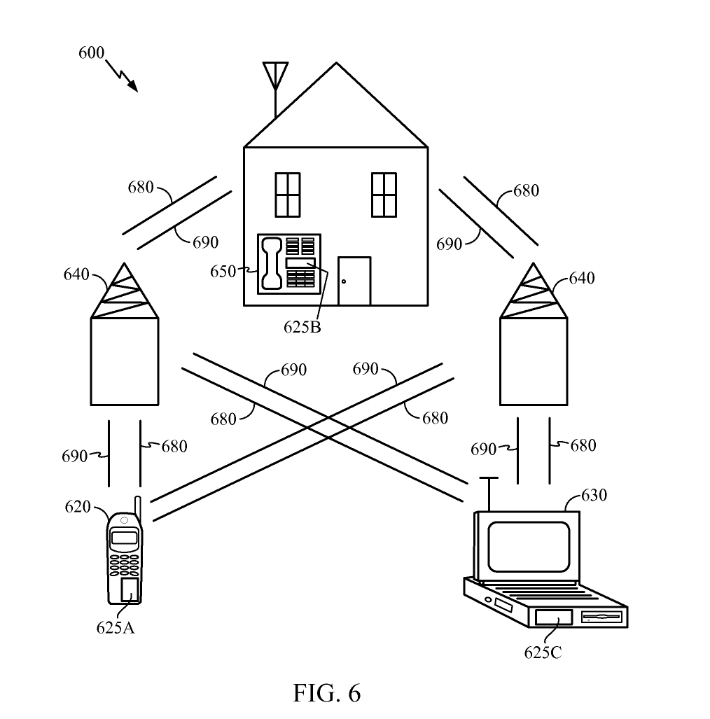

With reference to FIG. 6, an exemplary wireless communication system 600 is illustrated, in which an embodiment of the disclosure may be advantageously employed. For purposes of illustration, FIG. 6 shows three remote units 620, 630, and 650 and two base stations 640. It will be recognized that typical wireless communication systems may have many more remote units and base stations. Remote units 620, 630, and 650 include a global reset with replica for pulse latch pre-decoders circuitry 625A, 625B, and 625C, respectively, which are aspects of the disclosure as discussed further below. FIG. 6 shows forward link signals 680 from the base stations 640 and the remote units 620, 630, and 650 and reverse link signals 690 from the remote units 620, 630, and 650 to base stations 640.

In FIG. 6, remote unit 620 is shown as a mobile telephone, remote unit 630 is shown as a portable computer, and remote unit 650 is shown as a fixed location remote unit in a wireless local loop system. For example, the remote units may be cell phones, hand-held personal communication systems (PCS) units, portable data units such as personal data assistants, or fixed location data units such as meter reading equipment. Although FIG. 6 illustrates remote units according to the teachings of the disclosure, the disclosure is not limited to these exemplary illustrated units. The disclosure may be suitably employed in any device which includes a write sensor for selective word line boosting.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithm steps described in connection with the embodiments disclosed herein may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present invention.

The methods, sequences and/or algorithms described in connection with the embodiments disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

In some aspects, the teachings herein can be employed in a multiple-access system capable of supporting communication with multiple users by sharing the available system resources (e.g., by specifying one or more of bandwidth, transmit power, coding, interleaving, and so on). For example, the teachings herein can be applied to any one or combinations of the following technologies: Code Division Multiple Access (CDMA) systems, Multiple-Carrier CDMA (MCCDMA), Wideband CDMA (W-CDMA), High-Speed Packet Access (HSPA, HSPA+) systems, Time Division Multiple Access (TDMA) systems, Frequency Division Multiple Access (FDMA) systems, Single-Carrier FDMA (SC-FDMA) systems, Orthogonal Frequency Division Multiple Access (OFDMA) systems, or other multiple access techniques. A wireless communication system employing the teachings herein can be designed to implement one or more standards, such as IS-95, cdma2000, IS-856, W-CDMA, TDSCDMA, and other standards. A CDMA network can implement a radio technology such as Universal Terrestrial Radio Access (UTRA), cdma2000, or some other technology. UTRA includes W-CDMA and Low Chip Rate (LCR). The cdma2000 technology covers IS-2000, IS-95 and IS-856 standards. A TDMA network can implement a radio technology such as Global System for Mobile Communications (GSM). An OFDMA network can implement a radio technology such as Evolved UTRA (E-UTRA), IEEE 802.11, IEEE 802.16, IEEE 802.20, Flash-OFDM®, etc. UTRA, E-UTRA, and GSM are part of Universal Mobile Telecommunication System (UMTS). The teachings herein can be implemented in a 3GPP Long Term Evolution (LTE) system, an Ultra-Mobile Broadband (UMB) system, and other types of systems. LTE is a release of UMTS that uses E-UTRA. UTRA, E-UTRA, GSM, UMTS and LTE are described in documents from an organization named “3rd Generation Partnership Project” (3GPP), while cdma2000 is described in documents from an organization named “3rd Generation Partnership Project 2” (3GPP2). Although certain aspects of the disclosure can be described using 3GPP terminology, it is to be understood that the teachings herein can be applied to 3GPP (e.g., Rel99, Rel5, Rel6, Rel7) technology, as well as 3GPP2 (e.g., 1×RTT, 1xEV-DO RelO, RevA, RevB) technology and other technologies. The techniques can be used in emerging and future networks and interfaces, including Long Term Evolution (LTE).

Further, many embodiments are described in terms of sequences of actions to be performed by, for example, elements of a computing device. Various actions described herein can be performed by a specific circuit (e.g., an application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects of the invention may be embodied in a number of different forms, all of which have been contemplated to be within the scope of the claimed subject matter. In addition, for each of the embodiments described herein, a corresponding circuit of any such embodiments may be described herein as, for example, “logic configured to” perform a described action.

Accordingly, an embodiment of the invention can include a computer readable media embodying a method described herein. Accordingly, the invention is not limited to illustrated examples and any means for performing the functionality described herein are included in embodiments of the invention.

While the foregoing disclosure shows illustrative embodiments of the invention, it should be noted that various changes and modifications could be made herein without departing from the scope of the invention as defined by the appended claims. The functions, steps and/or actions of the method claims in accordance with the embodiments of the invention described herein need not be performed in any particular order. Furthermore, although elements of the invention may be described or claimed in the singular, the plural is contemplated unless limitation to the singular is explicitly stated.

What is claimed is:

1. A circuit comprising:
a data path comprising a launching pulse latch and a hold pulse latch; and
a system clock to trigger the launching pulse latch on rising edges of the system clock and to trigger the hold pulse latch on falling edges of the system clock to make a hold time race through condition frequency dependent.

2. The circuit of claim 1, further comprising at least one combinational logic circuitry, wherein the at least one combinational logic circuitry is placed within the data path.

3. The circuit of claim 1, wherein the hold pulse latch is configured to operate in a dual mode capacity acting as a buffer latch at high frequencies and a hold pulse latch at low frequencies.

4. The circuit of claim 1, further comprising a capture pulse latch configured to capture data from the data path after passing through the hold pulse latch.

5. The circuit of claim 1, further comprising:
a first pulse enable input for the hold pulse latch;
a second pulse enable input for the launching pulse latch;
a third pulse enable input for a capture pulse latch; and
an OR logic gate configured to OR the first pulse enable input with the second and third pulse enable inputs to form a fan in logic.

6. The circuit of claim 1, wherein the hold pulse latch is further configured to transfer data to at least one combinational logic circuit when the falling edge of the system clock is triggered.

7. The circuit of claim 6, wherein triggering the falling edge of the system clock gates the data transferred from the launching pulse latch to the at least one combinational logic circuit by half a cycle of the system clock.

8. The circuit of claim 7, further comprising a capture pulse latch input, wherein reception of data at the capture pulse latch input is dependent on an output of the hold pulse latch.

9. The circuit of claim 8, wherein the output of the hold pulse latch is dependent on when the falling edge of the system clock is triggered and wherein the period of the system clock is manipulated to directly affect the triggering of the hold pulse latch output.

10. The circuit of claim 9, wherein an increase in system clock period results in an increased delay of the hold pulse latch output.

11. The circuit of claim 1, wherein the hold pulse latch is strategically placed within the circuit at high input voltages, and wherein the hold pulse latch is pulsed at low voltages to save power consumption.

12. A method comprising:
triggering a launching pulse latch with a rising edge of a system clock; and
triggering a hold pulse latch with a falling edge of the system clock; wherein the launching pulse latch and the hold pulse latch form part of a data path.

13. The method of claim 12, further comprising providing at least one combinational logic circuitry, wherein the at least one combinational logic circuitry is placed within the data path.

14. The method of claim 12, further comprising configuring the hold pulse latch to operate in a dual mode capacity acting as a buffer latch at high frequencies and a hold pulse latch at low frequencies.

15. The method of claim 12, further comprising providing a capture pulse latch configured to capture data from the data path after passing through the hold pulse latch.

16. The method of claim 12, further comprising:
providing a first pulse enable input for the hold pulse latch;
enabling a second pulse enable input for the launching pulse latch;
providing a third pulse enable input for a capture pulse latch; and
connecting an OR logic gate configured to OR the first pulse enable input with the second and third pulse enable inputs to form a fan in logic.

17. The method of claim 12, further comprising configuring the hold pulse latch to transfer data to at least one combinational logic circuit when the falling edge of the system clock is triggered.

18. The method of claim 17, wherein triggering the falling edge of the system clock gates the data transferred from the launching pulse latch to the at least one combinational logic circuit by half a cycle of the system clock.

19. The method of claim 18, further comprising a capture pulse latch input, wherein reception of data at the capture pulse latch input is dependent on an output of the hold pulse latch.

20. The method of claim 19, wherein the output of the hold pulse latch is dependent on when the falling edge of the system clock and wherein the period of the system clock is manipulated to directly affect the triggering of the hold pulse latch output.

21. The method of claim 20, wherein an increase in system clock period results in an increased delay of the hold pulse latch output.

22. The method of claim 12, wherein the hold pulse latch is strategically placed within the circuit at high input voltages, and wherein the hold pulse latch is pulsed at low voltages to save power consumption.
